(19) United States
(12) Patent Application Publication
(10) Pub. No.: US 2025/0081527 A1
(43) Pub. Date: Mar. 6, 2025

(54) SEMICONDUCTOR DEVICES AND METHODS OF MANUFACTURING THEREOF WITH DIFFUSION CAP LAYERS

(71) Applicant: Taiwan Semiconductor Manufacturing Company, Ltd., Hsinchu (TW)

(72) Inventors: Kuei-Yu Kao, Hsinchu (TW); Chiung-Yu Cho, Hsinchu (TW); Ming-Ching Chang, Hsinchu (TW)

(73) Assignee: Taiwan Semiconductor Manufacturing Company, Ltd., Hsinchu (TW)

(21) Appl. No.: 18/459,531

(22) Filed: Sep. 1, 2023

(51) Int. Cl. H01L 29/423; H01L 29/49; H01L 29/66

(52) U.S. Cl. CPC H10D 30/6735; H10D 30/014; H10D 30/031; H10D 30/6739; H10D 64/017; H10D 30/43; H10D 30/6736; H10D 30/6757

(57) ABSTRACT

Semiconductor devices and methods for forming the semiconductor devices using diffusion cap layers are provided. The semiconductor devices include a plurality of semiconductor layers vertically separated from one another, a gate structure that comprises a lower portion and an upper portion, wherein the lower portion wraps around each of the plurality of semiconductor layers, and a plurality of diffusion cap layers disposed between and separating the plurality of semiconductor layers and the gate structure. In some embodiments, the plurality of diffusion cap layers function as diffusion barriers for the plurality of semiconductor layers.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically represents a perspective view of a gate-all-around (GAA) field-effect-transistor (FET) device in accordance with some embodiments;

FIG. 2 is a cross-sectional view of a portion of the GAA FET device of FIG. 1 in accordance with some embodiments;

FIG. 3 is a cross-sectional view of an isolated portion of the GAA FET device of FIG. 1 in accordance with some embodiments;

FIG. 4 is a flowchart illustrating an exemplary method for making a semiconductor device in accordance with some embodiments; and

FIGS. 5, 6, 7, 8, 9, 10, 11, and 12 include cross-sectional views of an example semiconductor device (or a portion of the example GAA FET device) during various fabrication stages, made by the method of FIG. 4, in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

Embodiments of the present disclosure are discussed in the context of forming a gate-all-around (GAA) field-effect-transistor (FET) device. In some embodiments, a fin is formed including a number of first semiconductor layers and a number of second semiconductor layers, which serve as sacrificial layers and channel layers, respectively, and diffusion cap layers disposed therebetween, which serve as diffusion barriers between the first semiconductor layers and the second semiconductor layers. A dummy gate structure is formed over the fin with the etch stop layer therebetween. A gate spacer is then formed on sidewalls of the dummy gate structure. Next, source/drain structures are formed on opposite sides of the dummy gate structure, with an interlayer dielectric (ILD) overlaying them. Upon forming the ILD, the dummy gate structure, portions of the etch stop layer, and portions of the sacrificial layers are removed to form and extend a gate trench. An active gate structure is next formed in the gate trench to wrap around each of the channel layers.

The semiconductor devices and methods disclosed herein provide the diffusion cap layers to reduce or eliminate diffusion between the first semiconductor layers and the second semiconductor layers and thereby reduce the likelihood of distortion of the shapes of the second semiconductor layers during the manufacturing process.

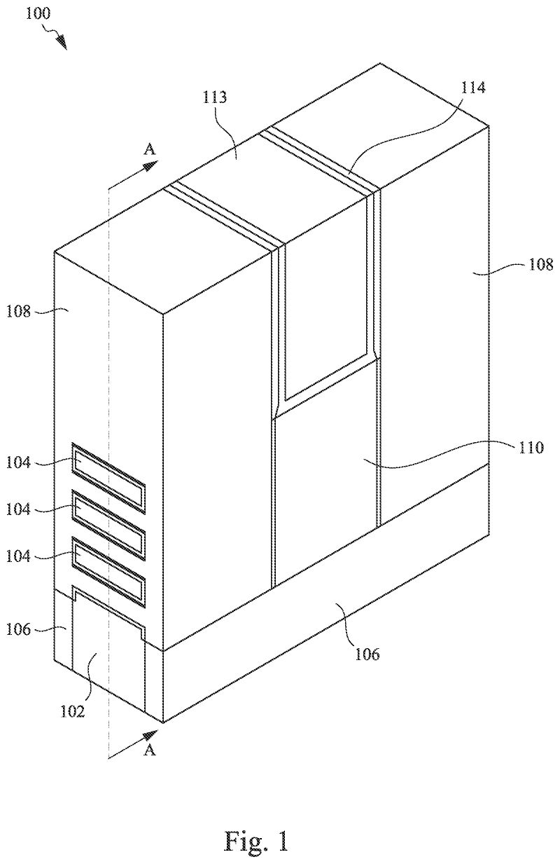

FIGS. 1, 2, and 3 illustrate perspective, cross-sectional, and isolated cross-sectional views, respectively, of an example GAA FET device 100, in accordance with various embodiments. The GAA FET device 100 includes a substrate 102 and a number of semiconductor layers 104 (also referred to as nanostructures (e.g., nanosheets, nanowires, etc.)) above the substrate 102. The semiconductor layers 104 are vertically separated from one another (relative to the orientation of FIG. 1). Isolation regions 106 are formed on opposing sides of a protruded portion of the substrate 102, with the semiconductor layers 104 disposed above the protruded portion. A gate structure 108 wraps around each of the semiconductor layers 104 (e.g., a full perimeter of each of the semiconductor layers 104). In this example, the gate structure 108 includes a gate dielectric layer 107 and a gate metal layer 109. Source/drain structures 110 are disposed on opposing sides of the gate structure 108. Source/drain structures may refer to a source or a drain, individually or collectively, dependent upon the context. An interlayer dielectric (ILD) 113 is disposed over the source/drain structure 110 with a contact etch stop layer (CESL) 111 therebetween. Inner spacers 120 are located along sidewalls of the gate structure 108 between the semiconductor layers 104. Gate spacers 114 are disposed between the gate structure 108 and the CESL 111. In this example, the gate spacers 114 include first conformal layers 116 along sidewalls of the gate structure 108 and second conformal layers 118 along sidewalls of the CESL 111. Intermediate or diffusion cap layers 105 are disposed between the semiconductor layers 104 and the gate structure 108 and the inner spacers 120. The diffusion cap layers 105 are configured to reduce the likelihood of distortion of the shapes of the semiconductor layers 104 during the manufacturing process and thereby promote a reduction of resistance across the semiconductor layers 104. For example, diffusion cap layers 105 may reduce or eliminate diffusion between the semiconductor layers 104 and sacrificial semiconductor layers therebetween (not shown; removed during manufacturing process).

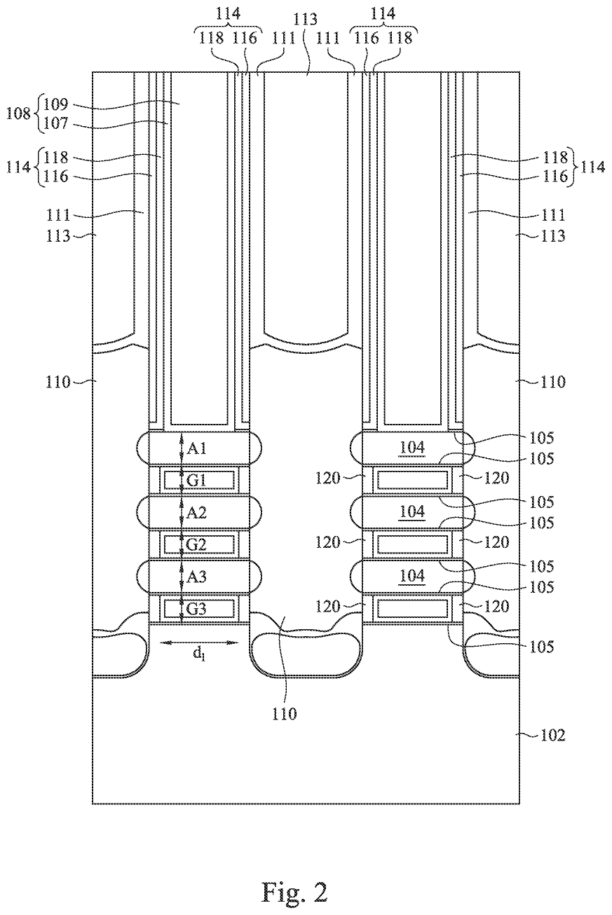

In some embodiments, the semiconductor layers 104 each have heights (e.g., A1, A2, and A3 in FIG. 2) of about 8 to 9 nanometers, wherein the heights are measured along directions normal to a first direction (d₁) extending along the semiconductor layers 104 between the source/drain structures 110. In some embodiments, regions of the gate structure 108 that are disposed between the semiconductor layers 104 and the source/drain structures 110 each have heights (e.g., G1, G2, and G3 in FIG. 2) normal to the first direction of about 6 to 7 nanometers.

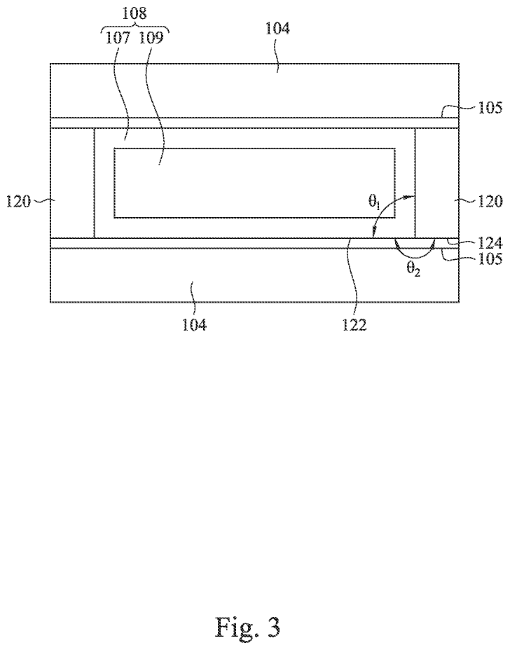

In some embodiments, the regions of the gate structure 108 disposed between the semiconductor layers 104 and the source/drain structures 110 have cross-sectional shapes along the first direction having inner corner angles (e.g., 0θ₁ in FIG. 3) of about 90 to 105 degrees. In some embodiments, first surfaces 122 of the gate structure 108 and first surfaces 124 of the inner spacers 120 define an angle (e.g., θ₂ in FIG. 3) therebetween of about 165 to 180 degrees, wherein the first surfaces 122 of the gate structure 108 and the first surfaces 124 of the inner spacers 120 are both in contact with the diffusion cap layers 105.

FIGS. 1-3 depict a simplified GAA FET device, and thus, it should be understood that one or more features of a completed GAA FET device may not be shown in FIGS. 1-3. Further, FIG. 1 is provided as a reference to illustrate a number of cross-sections in subsequent figures. As indicated, Cross-section A-A extends along a longitudinal axis of the semiconductor layers 104 and in a direction of a current flow between the source/drain structures (e.g., in the Y direction). Subsequent figures refer to this reference cross-section for clarity. For example, FIGS. 2 and 3 depict portions of the GAA FET device of FIG. 1 along the Cross-section A-A.

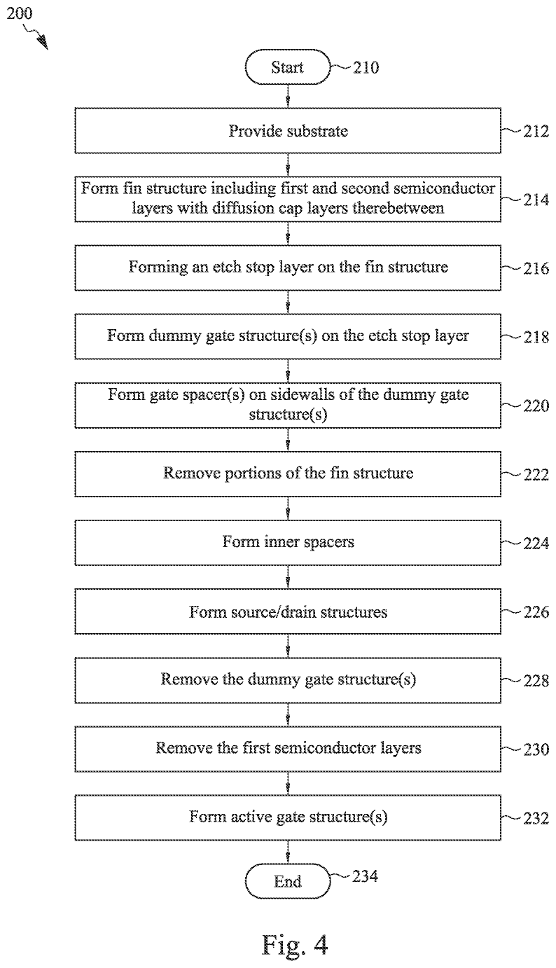

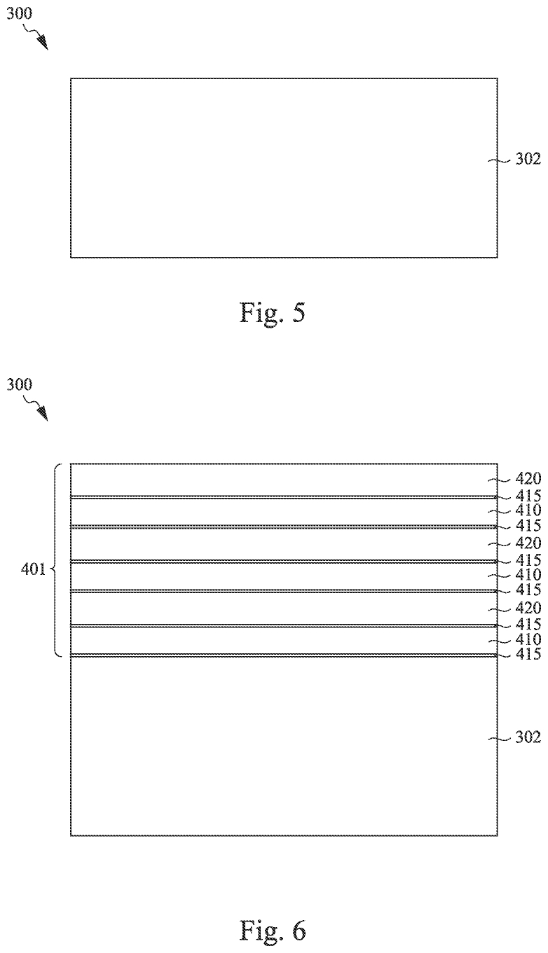

FIG. 4 illustrates a flowchart of a method 200 for forming a semiconductor device, such as a non-planar transistor device, according to one or more embodiments of the present disclosure. For example, at least some of the operations (or steps) of the method 200 can be used to form a FinFET device, a GAA FET device (e.g., the GAA FET device 100), a nanosheet transistor device, a nanowire transistor device, a vertical transistor device, or the like. It is noted that the method 200 is merely an example, and is not intended to limit the present disclosure. Accordingly, it is understood that additional operations may be provided before, during, and after the method 200 of FIG. 4, and that some other operations may only be briefly described herein. For convenience, certain operations of the method 200 will be described in reference to cross-sectional views of an example semiconductor device 300 at various fabrication stages as shown in FIGS. 5-12, respectively. However, the method 200 is not limited to the exemplary semiconductor device 300 or the examples shown in FIGS. 5-12.

The operations illustrated in FIGS. 5-12 are intended to produce a GAA FET device similar to the GAA FET device 100 shown in FIGS. 1-3. It should be understood that the semiconductor device 300 may include a number of other devices such as, but not limited to, inductors, fuses, capacitors, coils, etc., which are not shown in FIGS. 5-12 for purposes of clarity of illustration. The cross-sectional views of FIGS. 5-12 are in a direction perpendicular to the lengthwise direction of an active/dummy gate structure of the semiconductor device 300 (e.g., cross-section A-A indicated in FIG. 1).

The method 200 may start at 210. At 212, the method 200 includes providing a substrate 302, as presented in FIG. 5. The substrate 302 may be a semiconductor substrate, such as a bulk semiconductor, a semiconductor-on-insulator (SOI) substrate, or the like, which may be doped (e.g., with a p-type or an n-type dopant) or undoped. The substrate 302 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 302 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

At 214, the method 200 includes forming a fin structure 401 including a number of first semiconductor layers 410 and a number of second semiconductor layers 420 alternately disposed on top of one another (e.g., along the Z-direction) with a number of diffusion cap layers 415 therebetween (and on the substrate 302) to form a stack on the substrate 302. For example, a first of the diffusion cap layers 415 is disposed over the substrate 302, a first of the first semiconductor layers 410 is disposed over the first diffusion cap layers 415, then a second of the diffusion cap layers 415 is disposed over the first of the first semiconductor layers 410, then a first of the second semiconductor layers 420 is disposed over the second of the diffusion cap layers 415, then a third of the diffusion cap layers 415 is disposed over the first of the second semiconductor layers 420, then a second of the first semiconductor layers 410 is disposed over the third diffusion cap layer 415, so on and so forth. The fin structure 401 is elongated along a lateral direction (e.g., the Y-direction) of the substrate 302. The provide diffusion cap layers 415 are configured to reduce or eliminate diffusion between the first semiconductor layers 410 and the second semiconductor layers 420 during the manufacturing process. This in turn may reduce the likelihood of distortion of the shapes of the second semiconductor layers 420 and thereby promote a reduction of resistance across the second semiconductor layers 420.

The stack may include any number of alternately disposed first and second semiconductor layers 410 and 420, respectively, with the diffusion cap layers 415 therebetween. For example, in FIG. 6, the stack includes three of the first semiconductor layers 410, with two of the second semiconductor layers 420 alternatingly disposed therebetween, with another of the second semiconductor layers 420 being the topmost of the semiconductor layers 410 and 420, and with a total of six diffusion cap layers 415 disposed between the semiconductor layers 410 and 420 and the substrate 302. It should be understood that the semiconductor device 300 can include any number of first semiconductor layers 410, any number of second semiconductor layers 420, and any number of diffusion cap layers 415 with either one of the first or second semiconductor layers 410 and 420 being the topmost semiconductor layer of the fin structure 401, while remaining within the scope of the present disclosure.

The semiconductor layers 410 and 420 may have respective different thicknesses. Further, the first semiconductor layers 410 may have different thicknesses from one layer to another layer. The second semiconductor layers 420 may have different thicknesses from one layer to another layer. The thickness of each of the semiconductor layers 410 and 420 may range, for example, from few nanometers to few tens of nanometers. The first layer (e.g., closest to the substrate 302) of the stack may be thicker than other semiconductor layers 410 and 420. In an embodiment, each of the first semiconductor layers 410 has a thickness ranging from about 5 nanometers (nm) to about 20 nm (e.g., about 6 nm to 7 nm), each of the second semiconductor layers 420 has a thickness ranging from about 5 nm to about 20 nm (e.g., about 8 nm to 9 nm), and each of the diffusion cap layers 415 has a thickness ranging from about 1 nm to about 4 nm (e.g., about 1 nm to 2 nm). In some embodiments, the thickness of the diffusion cap layers 415 of 1 nm or greater provides a sufficient diffusion barrier to impede, reduce, or eliminate diffusion between the first semiconductor layers 410 and the second semiconductor layers 420 and thereby reduce the likelihood of distortion of the shapes of the second semiconductor layers 420 during the manufacturing process. In some embodiments, the thickness of the diffusion cap layers 415 of 4 nm or less provide sufficient space for the first semiconductor layers 410 (and portions of active gate structures 1500A-B that eventually replace the first semiconductor layers 410, described below) and thereby promote a reduction in resistance of channels electrically coupling source/drain structures 910A-C (described below).

The semiconductor layers 410 and 420 have different compositions. In various embodiments, the semiconductor layers 410 and 420 have compositions that provide for different oxidation rates and/or different etch selectivity between the semiconductor layers 410 and 420. In an embodiment, the first semiconductor layers 410 include silicon germanium (Si₁₋ₓGeₓ), and the second semiconductor layers include silicon (Si). In an embodiment, each of the semiconductor layers 420 is silicon that may be undoped or substantially dopant free (i.e., having an extrinsic dopant concentration from about 0 cm⁻³ to about 1×10¹⁷ cm⁻³), where for example, no intentional doping is performed when forming the second semiconductor layers 420 (e.g., of silicon). The diffusion cap layers 415 have compositions that reduce a likelihood of diffusion between the semiconductor layers 410 and 420. In an embodiment, the diffusion cap layers 415 include silicon nitride (SiN).

In various embodiments, the semiconductor layers 420 may be intentionally doped. For example, when the semiconductor device 300 is configured in n-type (and operates in an enhancement mode), each of the semiconductor layers 420 may be silicon that is doped with a p-type dopant such as boron (B), aluminum (Al), indium (In), and gallium (Ga); and when the semiconductor device 300 is configured in p-type (and operates in an enhancement mode), each of the semiconductor layers 420 may be silicon that is doped with an n-type dopant such as phosphorus (P), arsenic (As), and antimony (Sb). In another example, when the semiconductor device 300 is configured in n-type (and operates in a depletion mode), each of the semiconductor layers 420 may be silicon that is doped with an n-type dopant instead; and when the semiconductor device 300 is configured in p-type (and operates in a depletion mode), each of the semiconductor layers 420 may be silicon that is doped with a p-type dopant instead. In some embodiments, each of the semiconductor layers 410 is Si-Ge and includes less than 50% (x<0.5) Ge in molar ratio. For example, Ge may comprise about 15% to 35% of the semiconductor layers 410 of Si₁₋ₓGeₓ, in molar ratio. Furthermore, the first semiconductor layers 410 may include different compositions among them, and the second semiconductor layers 420 may include different compositions among them.

Either of the semiconductor layers 410 and 420 may include other materials, for example, a compound semiconductor material such as silicon carbide, gallium arsenide, gallium phosphide, indium phosphide, indium arsenide, and/or indium antimonide, an alloy semiconductor material such as GaAsP, AlInAs, AlGaAs, InGaAs, GaInP, and/or GaInAsP, or combinations thereof. The materials of the semiconductor layers 410 and 420 may be chosen based on providing differing oxidation rates and/or etch selectivity.

In various examples, the fin structure 401 may be formed by initially forming the first semiconductor layers 410, the second semiconductor layers 420, and the diffusion cap layers 415 in an interleaved manner to define the stack, and then patterning the stack and the semiconductor substrate 302.

In various examples, the semiconductor layers 410 and 420 and the diffusion cap layers 415 can be epitaxially grown from the semiconductor substrate 302. For example, each of the semiconductor layers 410 and 420 and the diffusion cap layers 415 may be grown by a molecular beam epitaxy (MBE) process, a chemical vapor deposition (CVD) process such as a metal organic CVD (MOCVD) process, and/or other suitable epitaxial growth processes. During the epitaxial growth, the crystal structure of the semiconductor substrate 302 extends upwardly, resulting in the semiconductor layers 410 and 420 and the diffusion cap layers 415 having the same crystal orientation with the semiconductor substrate 302.

In various example, the stack and the substrate 302 may be patterned using, for example, photolithography and etching techniques. For example, a mask layer (which can include multiple layers such as, for example, a pad oxide layer and an overlying pad nitride layer) is formed over the topmost semiconductor layer (e.g., 420 in FIG. 6). The pad oxide layer may be a thin film comprising silicon oxide formed, for example, using a thermal oxidation process. The pad oxide layer may function as an adhesion layer between the topmost semiconductor layer 420 (or a topmost semiconductor layer 410 in some other embodiments) and the overlying pad nitride layer. In some embodiments, the pad nitride layer is formed of silicon nitride, silicon oxynitride, silicon carbonitride, the like, or combinations thereof. The pad nitride layer may be formed using low-pressure chemical vapor deposition (LPCVD) or plasma enhanced chemical vapor deposition (PECVD), for example.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask.

The patterned mask can be subsequently used to pattern exposed portions of the first and second semiconductor layers 410 and 420, the diffusion cap layers 415, and the substrate 302 to form trenches (or openings), thereby defining the fin structures 401 between adjacent trenches. When multiple fin structures 401 are formed, such a trench may be disposed between any adjacent ones of the fin structures 401. In some embodiments, the fin structure 401 is formed by etching trenches in the first and second semiconductor layers 410 and 420, the diffusion cap layers 415, and the substrate 302 using, for example, reactive ion etch (ME), neutral beam etch (NBE), the like, or combinations thereof. The etch may be anisotropic. In some embodiments, the trenches may be strips (when viewed from the top) parallel to each other, and closely spaced with respect to each other. In some embodiments, the trenches may be continuous and surround the fin structure 401.

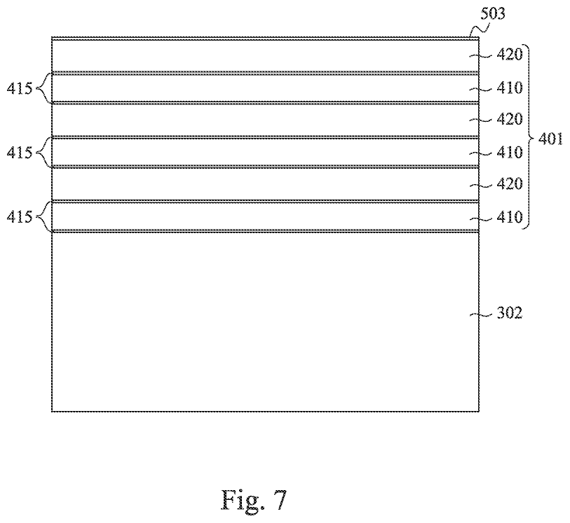

At 216, the method 200 includes forming an etch stop layer (ESL) 503 on the uppermost of the first semiconductor layer 410 or the second semiconductor layer 420 as shown in FIG. 7. The ESL 503 can be formed over the fin structure 401. In some other embodiments, the ESL 503 may be formed over only a top surface of the fin structure 401. The ESL 503 may be formed by a deposition process, such as chemical vapor deposition (CVD) (e.g., plasma enhanced chemical vapor deposition (PECVD), high aspect ratio process (HARP), or combinations thereof) process, atomic layer deposition (ALD) process, another applicable process, or combinations thereof. The ESL 503 may be formed of a material that is resistant to an etchant used to remove portions of dummy gate structures 510A-B formed in subsequent steps of the method 200 discussed in more detail below. In some examples, the ESL 503 may include or be formed of silicon monoxide (SiO).

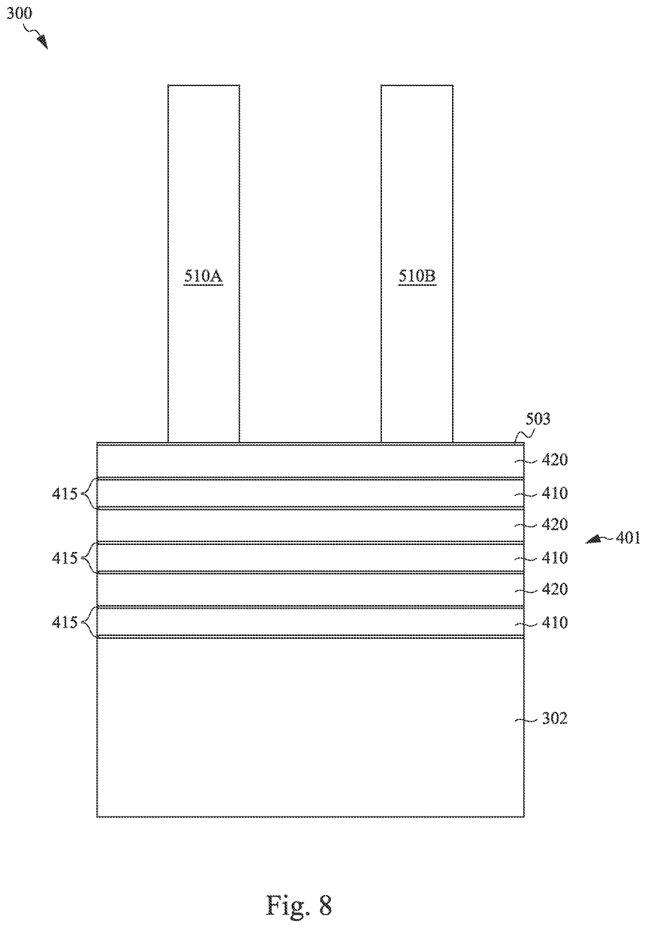

At 218, the method 200 includes forming one or more dummy gate structures 510A-B over the ESL 503 as represented in FIG. 8. The dummy gate structures 510A-B can each extend along a lateral direction (e.g., the X-direction) perpendicular to the lateral direction along which the fin structure 401 extends. The dummy gate structures 510A-B may be placed where respective active (e.g., metal) gate structures are later formed, in various embodiments. For example, in FIG. 8, each of the dummy gate structures 510A-B is placed over a respective portion of fin structure 401, with the ESL 503 sandwiched therebetween. Such an overlaid portion of the fin structure 401 is later formed as a conduction channel, which includes portions of the second semiconductor layers 420, and the dummy gate structures 510A-B are each replaced with an active gate structure 1500A-B to warp around each of the portions of the second semiconductor layers 420.

The dummy gate structures 510A-B each include a material unfavorable for epitaxial growth, in some embodiments. As such, in a later stage of process where epitaxial growth is performed (e.g., when forming source/drain structures 910A-C), the epitaxial growth can be significantly limited around the dummy gate structures 510A-B (e.g., along sidewalls of the dummy gate structures 510A-B). In some embodiments, the dummy gate structures 510A-B can each include one or more silicon-based dielectric materials such as, for example, silicon oxide, silicon nitride, silicon oxynitride, silicon carbide, silicon carbonitride, silicon oxycarbonitride, silicon oxycarbide, multilayers thereof, or combinations thereof, and may be deposited. In some embodiments, the dummy gate structures 510A-B can each include one or more metal-based materials such as, for example, cobalt, tungsten, hafnium oxide, aluminum oxide, or combinations thereof, and may be deposited.

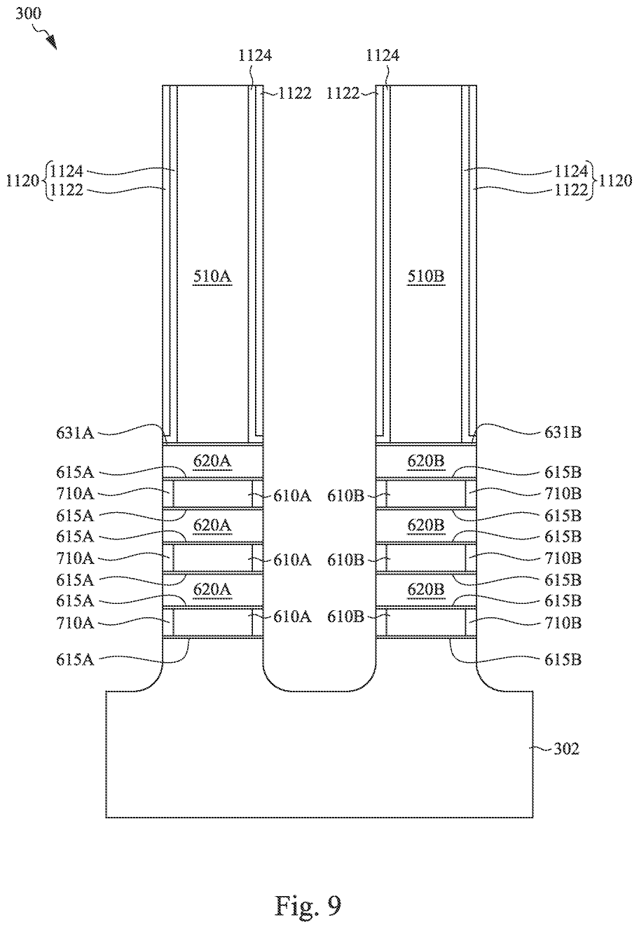

FIG. 9 is a cross-sectional view of the semiconductor device 300 having portions of the ESL 503 that do not underlie the dummy gate structures 510A-B removed, at one of the various stages of fabrication. The portions of the ESL 503 that do not underlie the dummy gate structures 510A-B may be removed by, for example, an etching process having one or more steps. By removing such portions of the ESL 503, a topmost semiconductor layer 420 of the fin structure 401 is exposed.

The etching process can include a plasma etching process, which can have a certain amount of anisotropic characteristic. In such a plasma etching process (including radical plasma etching, remote plasma etching, and other suitable plasma etching processes), gas sources such as chlorine (C₁₂), hydrogen bromide (HBr), carbon tetrafluoride (CF₄), fluoroform (CHF₃), difluoromethane (CH₂F₂), fluoromethane (CH₃F), hexafluoro-1,3-butadiene (C₄F₆), boron trichloride (BCl₃), sulfur hexafluoride (SF₆), hydrogen (H₂), nitrogen trifluoride (NF₃), hydrogen fluoride (HF), ammonia (NH₃), and other suitable gas sources and combinations thereof can be used with passivation gases such as nitrogen (N₂), oxygen (O₂), carbon dioxide (CO₂), sulfur dioxide (SO₂), carbon monoxide (CO), methane (CH₄), silicon tetrachloride (SiCl₄), and other suitable passivation gases and combinations thereof. Moreover, for the plasma etching process, the gas sources and/or the passivation gases can be diluted with gases such as argon (Ar), helium (He), neon (Ne), and other suitable dilutive gases and combinations thereof to control the above-described etching rates. As a non-limiting example, a source power of 10 watts to 4000 watts, a bias power of 0 watts to 4000 watts, a pressure of 1 millitorr to 8 torr, and an etch gas flow of 0 standard cubic centimeters per minute (sccm) to 5000 sccm, such as about 20 sccm to 3000 sccm, minute may be used in the etching process. However, it is noted that source powers, bias powers, pressures, and flow rates outside of these ranges are also contemplated.

In another example, the etching process can include a wet etching process, which can have a certain amount of isotropic characteristic, in combination with the plasma etching process. In such a wet etching process, a main etch chemical such as hydrofluoric acid (HF), fluorine (F₂), and other suitable main etch chemicals and combinations thereof can be used with assistive etch chemicals such as sulfuric acid (H₂SO₄), hydrogen chloride (HCl), hydro gen bromide (HBr), ammonia (NH₃), phosphoric acid (H₃PO₄), and other suitable assistive etch chemicals and combinations thereof as well as solvents such as deionized water, alcohol, acetone, and other suitable solvents and combinations thereof to control the above-described etching rates.

The dummy gate structures 510A-B can serve as a mask to etch the non-overlaid portions of the ESL 503. As a result, along the Z direction, newly formed sidewalls of each of the remaining portions of the ESL 503 are aligned with sidewalls of the dummy gate structure 510A or 510B. For example, in FIG. 9, ESL 631A is the remaining portion of the ESL 503 overlaid by the dummy gate structure 510A, and ESL 631B is the remaining portion of the ESL 503 overlaid by the dummy gate structure 510B.

At 220, the method 200 includes forming gate spacers 1120 as also represented in FIG. 9. The gate spacers 1120 are formed along sidewalls of the dummy gate structures 510A-B. The gate spacers 1120 can each be formed as a single conformal layer or a combination of two or more conformal layers, each of which lines a corresponding one of the sidewalls of the dummy gate structures 510A-B. It should be understood that any gate spacer, formed as a combination of any number of conformal layers, can be formed, while remaining within the scope of the present disclosure. In the example of FIG. 9, the gate spacers 1120 include a first conformal layer 1124 and a second conformal layer 1122.

In some embodiments, each of the conformal layers 1122 and 1124 may include a dielectric material selected from the group consisting of: silicon nitride, silicon oxynitride, silicon carbonitride, silicon carbide, silicon oxycarbide, the like, or combinations thereof. The conformal layers 1122 and 1124 may be formed using atomic layer deposition (ALD), low-pressure chemical vapor deposition (LPCVD) or plasma enhanced chemical vapor deposition (PECVD), for example. Each of the conformal layers may have a thickness ranging from about 2 angstroms (Å) to about 500 Å.

In some embodiments, the first conformal layer 1124 may be deposited on sidewalls of the dummy gate structures 510A-B and the topmost semiconductor layer 420. Next, the second conformal layer 1122 may be deposited on the first conformal layer 1124. Thereafter, portions of the conformal layers 1122 and 1124 located over the topmost semiconductor layer 420 may be removed, for example, with an etching process.

After the etching process, the gate spacers 1120 can include the second conformal layer 1122 having one sidewall exposed and the first conformal layer 1124 having an L-shaped profile. Specifically, the L-shaped first conformal layer 1124 includes a vertical portion and a horizontal portion, wherein the vertical portion is between the dummy gate structure 510A-B and the second conformal layer 1122 and the horizontal portion has one of its sidewalls exposed.

At 222, the method 200 includes removing portions of the fin structure 401 as also represented in FIG. 9. The dummy gate structures 510A-B can serve as a mask to etch the non-overlaid portions of the fin structure 401, which results in the fin structure 401 having one or more alternatingly stacks including remaining portions of the semiconductor layers 410 and 420 with remaining portions of the diffusion cap layers 415 therebetween. As a result, along the Z direction, newly formed sidewalls of the fin structures 401 are aligned with sidewalls of the dummy gate structure 510A or 510B. For example, in FIG. 9, semiconductor layers 610A and 620A, and diffusion cap layers 615A are the remaining portions of the semiconductor layers 410 and 420, and the diffusion cap layers 415 overlaid by the dummy gate structure 510A, respectively; and semiconductor layers 610B and 620B, and the diffusion cap layers 615B are the remaining portions of the semiconductor layers 410 and 420, and the diffusion cap layers 415 overlaid by the dummy gate structure 510B, respectively.

At 224, the method 200 includes forming first inner spacers 710A along respective etched ends of the semiconductor layers 610A and second inner spacers 710B along respective etched ends of the semiconductor layers 610B, as also represented in FIG. 9. To form the inner spacers 710A-B, respective end portions of each of the semiconductor layers 610A-B may first be removed. The end portions of the semiconductor layers 610A-B can be removed (e.g., etched) using a “pull-back” process to pull the semiconductor layers 610A-B back by an initial pull-back distance. Although in the illustrated embodiment of FIG. 9 the etched ends of each of the semiconductor layers 610A-B are approximately vertical (e.g., in parallel with the sidewalls of the dummy gate structures 510A-B), it should be understood that the etched ends may be curved inwardly or outwardly. In an example where the semiconductor layers 620A-B include silicon, the semiconductor layers 610A-B include silicon germanium (i.e., Si₁₋ₓGeₓ), and the diffusion cap layers include silicon nitride (SiN), the pull-back process may include a hydrogen chloride (HCl) gas isotropic etch process, which etches SiGe without attacking the silicon or nitrogen. As such, the semiconductor layers 620A-B and the diffusion cap layers 615A-B may remain intact during this process.

Next, the inner spacers 710A-B can be formed along the etched ends of each of the semiconductor layers 610A-B. Thus, the inner spacers 710A-B (e.g., their respective inner sidewalls) may follow the profile of the etched ends of the semiconductor layers 610A-B. In some embodiments, the inner spacers 710A-B can be formed conformally by chemical vapor deposition (CVD), or by monolayer doping (MLD) of nitride followed by spacer ME. The inner spacers 710A-B can be deposited using, for example, a conformal deposition process and subsequent isotropic or anisotropic etch back process to remove excess spacer material on the sidewalls of the stacks of the fin structure 401 and on a surface of the semiconductor substrate 302. A material of the inner spacers 710A-B can be formed from the same or different material as the dummy gate structures 510A-B. For example, the inner spacers 710A-B can be formed of silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

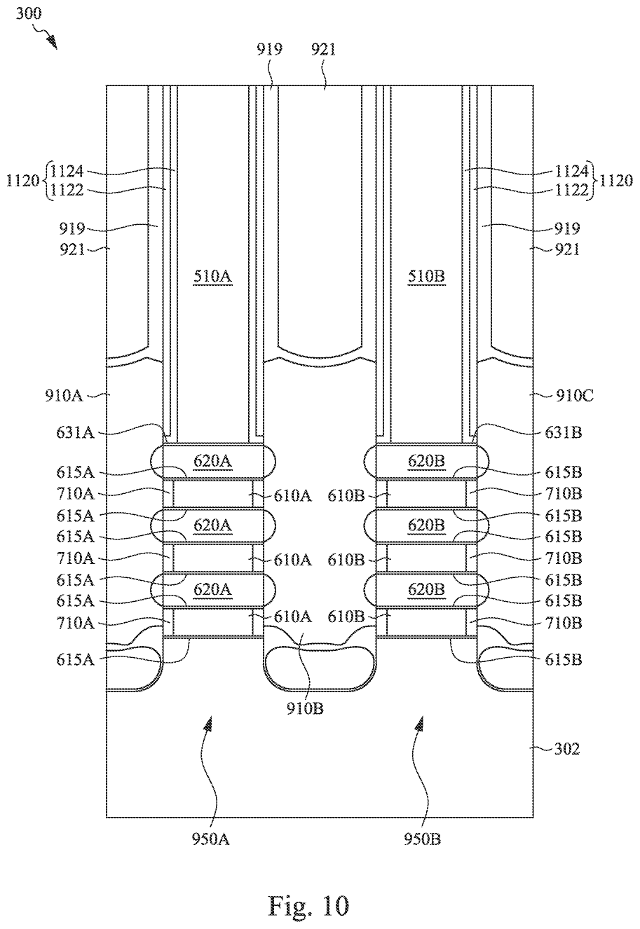

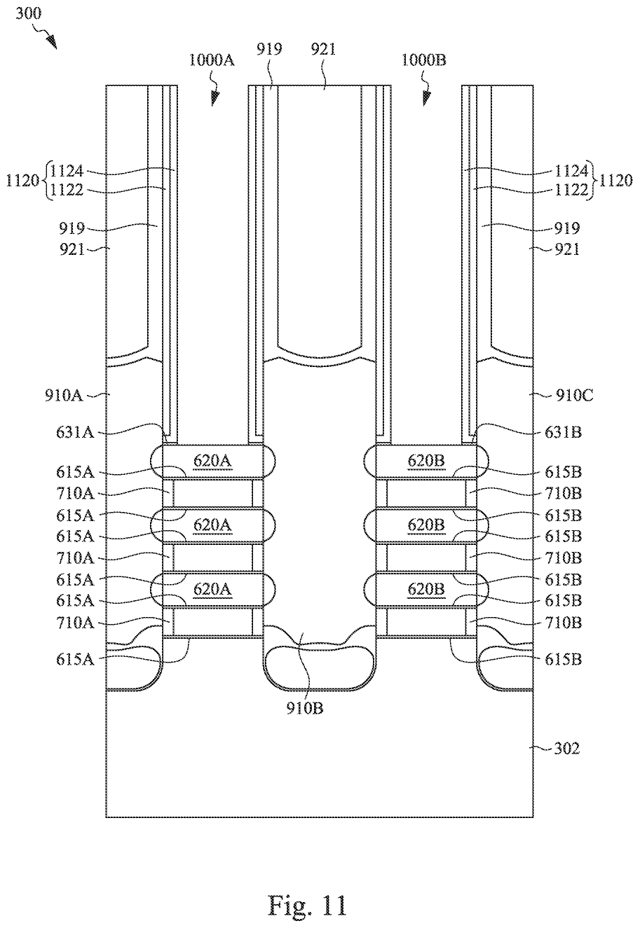

At 226, the method 200 includes forming source/drain structures 910A, 910B, and 910C, a contact etch stop layer (CESL) 919, and an interlayer dielectric (ILD) 921 as shown in FIG. 11. The source/drain structures 910A-C may be formed using, for example, an epitaxial layer growth process on exposed ends of each of the semiconductor layers 620A-B. In some embodiments, a bottom surface of the source/drain structures 910A-C may be leveled with the top surface of an isolation structure (not shown) that embeds a lower portion of the fin structure 401. In some other embodiments, the bottom surface of the source/drain structures 910A-C may be lower than the top surface of such an isolation structure. On the other hand, in some embodiments, a top surface of the source/drain structures 910A-C may be higher than a top surface of the topmost semiconductor layers 610A-B, as shown in FIG. 10. In some other embodiments, the top surface of the source/drain structures 910A-C may be leveled with or lower than the top surface of the topmost semiconductor layers 610A-B.

The source/drain structures 910A-C are electrically coupled to the respective semiconductor layers 620A-B. For example, the source/drain structures 910A-B can be electrically coupled to the semiconductor layers 620A; and the source/drain structures 910B-C can be electrically coupled to the semiconductor layers 620B. In various embodiments, the semiconductor layers 620A may collectively function as the conduction channel of a first GAA transistor (hereinafter “GAA transistor 950A”); and the semiconductor layers 620B may collectively function as the conduction channel of a second GAA transistor (hereinafter “GAA transistor 950B”). It should be noted that at this stage of fabrication, the GAA transistors 950A-B are not finished yet.

In-situ doping (ISD) may be applied to form doped source/drain structures 910A-C, thereby creating the junctions for the GAA transistors 950A-B. N-type and p-type FETs are formed by implanting different types of dopants to selected regions (e.g., the source/drain structures 910A-C) of the device to form the junction(s). N-type devices can be formed by implanting arsenic (As) or phosphorous (P), and p-type devices can be formed by implanting boron (B).

Upon forming the source/drain structures 910A-C, the CESL 919 can be formed by depositing a dielectric material over the partially formed GAA transistors 950A-B. The ILD 921 can then be formed by depositing an additional dielectric material in bulk over the CESL 919 and polishing the bulk oxides back (e.g., using CMP) to the level of the dummy gate structures 510A-B. The dielectric materials of the CESL 919 and the ILD 921 may include silicon oxide, phosphosilicate glass (PSG), borosilicate glass (BSG), boron-doped phosphosilicate glass (BPSG), undoped silicate glass (USG), or combinations thereof.

At 228, the method 200 includes removing the dummy gate structures 510A-B, and portions of the ESLs 631A-B as represented in FIG. 11. Subsequent to forming the ILD 921 (FIG. 10), the dummy gate structures 510A-B are removed, thereby forming gate trenches 1000A and 1000B, respectively. The dummy gate structures 510A-B can be removed by a known etching process, such as RIE or chemical oxide removal (COR). After the removal of the dummy gate structures 510A-B (forming the gate trenches 1000A-B), the top surface of the ESLs 631A-B are exposed. Although not shown, it should be appreciated that in addition to the top surface of the ESLs 631A-B, the sidewalls of each of the semiconductor layers 610A-B and 620A-B (facing the X-direction) may be exposed, in some embodiments.

The portions of the ESLs 631A-B that do not extend along the sidewalls of the gate trench 1000A-B may be removed by an etching process, which can include one or more steps. By removing such portions of the ESLs 631A-B, the top surface of the topmost semiconductor layers 620A-B is exposed. The etching process can include, for example, a plasma etching process, a wet etching process, or a combination thereof as described previously in relation to FIG. 9.

The remaining portions of the ESLs 631A-B, if any, each have a sidewall that is vertically aligned with a sidewall collectively formed by the conformal layers 1122 and 1124 of the gate spacers 1120. These vertically aligned sidewalls of the gate spacers 1120 are exposed in the gate trenches 1000A-B.

At 230, the method 200 includes removing the first semiconductor layers 610A-B also as shown in FIG. 11. The semiconductor layers 610A-B may be removed by applying a selective etch (e.g., a hydrochloric acid (HCl)), while leaving the semiconductor layers 620A-B and the diffusion cap layers 615A-B substantially intact. After the removal of the semiconductor layers 610A-B, respective bottom surface and/or top surfaces of each of the diffusion cap layers 615A-B may be exposed by the “extended” gate trenches 1000A-B, in accordance with various embodiments. For example, upon removing the semiconductor layers 610A-B, the gate trenches 1000A-B can be further extended from a region that is above the topmost semiconductor layers 610A-B to a region that is below the topmost semiconductor layers 610A-B. Consequently, the bottom surface of each of the topmost diffusion cap layers 615A-B can be exposed, and the respective top and bottom surfaces of each of the rest of the diffusion cap layers 615A-B can also be exposed.

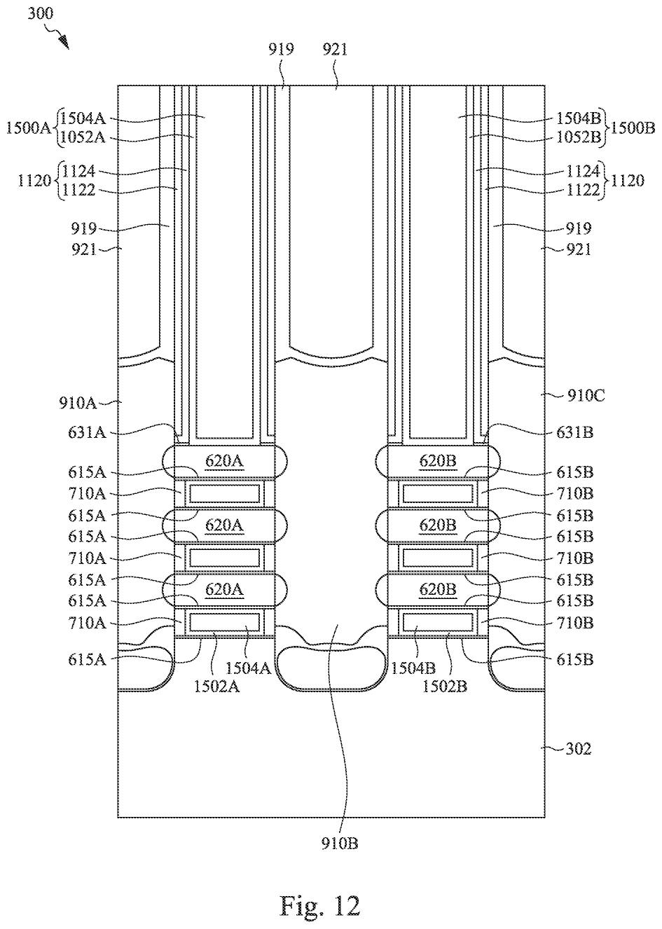

At 232, the method 200 includes forming one or more active gate structures 1500A and 1500B as shown in FIG. 12. The active gate structures 1500A-B may be formed in the extended gate trenches 1000A-B (FIG. 11), while leaving other components (e.g., the gate spacers 1120) substantially intact, and thus, the active gate structures 1500A-B can inherit the dimensions and profiles of the gate trenches 1000A-B, respectively. The upper portion may be surrounded by the gate spacers 1120, and the lower portion may wrap around each of the semiconductor layers 620A/B and the diffusion cap layers 615A/B.

In some embodiments, each of the active gate structures 1500A-B includes a gate dielectric and a gate metal. In such embodiments, the gate dielectric and gate metal can each be formed with one or more layers.

In the example of FIG. 12, gate dielectric layers 1502A-B and gate metal layers 1504A-B wrap around each of the semiconductor layers 620A-B and the diffusion cap layers 615A-B, for example, the top and bottom surfaces and sidewalls facing the X-direction. The gate dielectric layers 1502A-B may be formed of different high-k dielectric materials or a similar high-k dielectric material. Example high-k dielectric materials include a metal oxide, nitride, or a silicate of Hf, Al, Zr, Ta, La, Mg, Ba, Ti, Pb, and combinations thereof. The gate dielectric layers 1502A-B may include a stack of multiple high-k dielectric materials. The gate dielectric layers 1502A-B can be deposited using any suitable method, including, for example, molecular beam deposition (MBD), atomic layer deposition (ALD), PECVD, and the like. In some embodiments, the gate dielectric layers 1502A-B may optionally include a substantially thin oxide (e.g., SiO₂) layer, which may native oxide layer formed on the surface of each of the diffusion cap layers 615A-B.

The gate metal layers 1504A-B can wrap around each of the semiconductor layers 620A-B and the diffusion cap layers 615A-B with the gate dielectric layers 1502A-B disposed therebetween. Specifically, the gate metal layers 1504A-B can include a number of gate metal sections abutted to each other along the Z-direction. Each of the gate metal sections can extend not only along a horizontal plane (e.g., the plane expanded by the X-direction and the Y-direction), but also along a vertical direction (e.g., the Z-direction). As such, two adjacent ones of the gate metal sections can adjoin together to wrap around a corresponding one of the semiconductor layers 620A-B and the diffusion cap layers 615A-B, with the gate dielectric layers 1502A-B disposed therebetween.

The gate metal layers 1504A-B may include a stack of multiple metal materials. For example, the gate metal layers 1504A-B may be a p-type work function layer, an n-type work function layer, multi-layers thereof, or combinations thereof. The work function layer may also be referred to as a work function metal. Example p-type work function metals that may include TiN, TAN, Ru, Mo, Al, WN, ZrSi₂, MoSi₂, TaSi₂, NiSi₂, WN, other suitable p-type work function materials, or combinations thereof. Example n-type work function metals that may include Ti, Ag, TaAl, TaAlC, TiAlN, TAC, TACN, TaSiN, Mn, Zr, other suitable n-type work function materials, or combinations thereof. A work function value is associated with the material composition of the work function layer, and thus, the material of the work function layer is chosen to tune its work function value so that a target threshold voltage V, is achieved in the device that is to be formed. The work function layer(s) may be deposited by CVD, physical vapor deposition (PVD), ALD, and/or other suitable process.

The method 200 may end at 234.

The present disclosure therefore provides semiconductor devices and methods for forming the semiconductor devices using diffusion cap layers.

The semiconductor devices and methods disclosed herein provide diffusion cap layers (e.g., the diffusion cap layers 615A-B) which reduce or eliminate diffusion between the first semiconductor layers and the second semiconductor layers and thereby reduce the likelihood of distortion of the shapes of the second semiconductor layers during the manufacturing process. For example, in arrangements wherein the first semiconductor layers include silicon germanium and the second semiconductor layers include silicon, thermal energy produced during the process of producing the semiconductor may cause germanium to diffuse from the first semiconductor layers to the second semiconductor layers. When an etching process is used to remove the first semiconductor layers, portions of the second semiconductor layers that include the diffused germanium may also be etched and removed. In such examples, the second semiconductor layers may have distorted shapes which can increase resistance. In such examples, the diffusion cap layers 615A-B may be formed of, for example, silicon nitride to prevent diffusion of the germanium and thereby preserve the shape of the second semiconductor layers and thereby promote a reduction of resistance.

In one aspect of the present disclosure, a semiconductor device is disclosed. The semiconductor device includes a plurality of semiconductor layers vertically separated from one another, a gate structure that comprises a lower portion and an upper portion, wherein the lower portion wraps around each of the plurality of semiconductor layers, and a plurality of diffusion cap layers disposed between and separating the plurality of semiconductor layers and the gate structure. The plurality of diffusion cap layers function as diffusion barriers for the plurality of semiconductor layers.

In another aspect of the present disclosure, a semiconductor device is disclosed. The semiconductor device includes a fin structure disposed over a substrate having one or more semiconductor layers vertically separated from one another, a gate structure that comprises a lower portion and an upper portion, wherein the lower portion wraps around each of the one or more semiconductor layers of the fin structure, a plurality of intermediate layers disposed between and separating the plurality of semiconductor layers and the gate structure, and inner spacers vertically disposed between the plurality of semiconductor layers and separating the lower portion of the gate structure from source/drain structures.

In yet another aspect of the present disclosure, a method for fabricating a semiconductor device is disclosed. The method includes forming a fin structure on a substrate that extends along a first lateral direction of the substrate, wherein the fin structure includes a plurality of alternating first semiconductor layers, second semiconductor layers, and diffusion cap layers between the first semiconductor layers and the second semiconductor layers, wherein the diffusion cap layers function as diffusion barriers between the first semiconductor layers and the second semiconductor layers, forming an etch stop layer on the fin structure, forming a dummy gate structure over a portion of the fin structure, wherein the dummy gate structure extends along the substrate in a second direction perpendicular to the first lateral direction, wherein portions of the etch stop layer are between the fin structure and the dummy gate structure, lining sidewalls of the dummy gate structure with gate spacers, wherein the gate spacers and the fin structure are separated by the etch stop layer, removing portions of the fin structure not underlying the dummy gate structure, forming source/drain structures that are respectively coupled to ends of the fin structure, wherein the source/drain structures are formed in locations previously occupied by the portions of the fin structure, removing the dummy gate structure to form a gate trench, removing the first semiconductor layers such that the second semiconductor layers are vertically separated by one another by spaces, and forming an active gate structure in the gate trench that wraps around each of the second semiconductor layers of the fin structure by filling the spaces therebetween wherein the diffusion cap layers are disposed between and separate the active gate structure and the second semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of semiconductor layers vertically separated from one another;
a gate structure that comprises a lower portion and an upper portion, wherein the lower portion wraps around each of the plurality of semiconductor layers; and
a plurality of diffusion cap layers disposed between and separating the plurality of semiconductor layers and the gate structure, wherein the diffusion cap layers function as diffusion barriers for the plurality of semiconductor layers.

2. The semiconductor device of claim 1, wherein the plurality of diffusion cap layers each have a thickness of about 1 to 2 nanometers such that diffusion between the plurality of semiconductor layers is sufficiently impeded to prevent distortion of the plurality of semiconductor layers.

3. The semiconductor device of claim 1, wherein the plurality of semiconductor layers include silicon.

4. The semiconductor device of claim 1, wherein the plurality of diffusion cap layers include silicon nitride.

5. The semiconductor device of claim 1, wherein the plurality of semiconductor layers extend between and electrically couple source/drain structures along a first direction, regions of the lower portion of the gate structure are disposed between the plurality of semiconductor layers and the source/drain structures, wherein the plurality of semiconductor layers each have heights normal to the first direction of about 8 to 9 nanometers, and the regions of the lower portion of the gate structure each have heights normal to the first direction of about 6 to 7 nanometers.

6. The semiconductor device of claim 1, wherein the plurality of semiconductor layers extend between and electrically couple source/drain structures along a first direction, regions of the lower portion of the gate structure are disposed between the plurality of semiconductor layers and the source/drain structures, and the regions of the lower portion of the gate structure have cross-sectional shapes along the first direction having inner corner angles of about 90 to 105 degrees.

7. The semiconductor device of claim 1, further comprising inner spacers vertically disposed between the plurality of semiconductor layers and separating the lower portion of the gate structure from source/drain structures, wherein first surfaces of the lower portion of the gate structure and first surfaces of the inner spacers define an angle therebetween of about 165 to 180 degrees, wherein the first surfaces of the lower portion of the gate structure and the first surfaces of the inner spacers are both in contact with the plurality of diffusion cap layers.

8. A semiconductor device, comprising:
a fin structure disposed over a substrate having a plurality of semiconductor layers vertically separated from one another;
a gate structure that comprises a lower portion and an upper portion, wherein the lower portion wraps around each of the plurality of semiconductor layers of the fin structure;
a plurality of intermediate layers disposed between and separating the plurality of semiconductor layers and the gate structure; and
inner spacers vertically disposed between the plurality of semiconductor layers and separating the lower portion of the gate structure from source/drain structures.

9. The semiconductor device of claim 8, wherein the plurality of intermediate layers function as diffusion barriers for the plurality of semiconductor layers.

10. The semiconductor device of claim 8, wherein the plurality of intermediate layers each have a thickness of about 1 to 2 nanometers such that diffusion between the plurality of semiconductor layers is sufficiently impeded to prevent distortion of the plurality of semiconductor layers.

11. The semiconductor device of claim 8, wherein the plurality of semiconductor layers include silicon and the plurality of intermediate layers include silicon nitride.

12. The semiconductor device of claim 8, wherein the plurality of semiconductor layers extend between and electrically couple the source/drain structures along a first direction, regions of the lower portion of the gate structure are disposed between the plurality of semiconductor layers and the source/drain structures, wherein the plurality of semiconductor layers each have heights normal to the first direction of about 8 to 9 nanometers, and the regions of the lower portion of the gate structure each have heights normal to the first direction of about 6 to 7 nanometers.

13. The semiconductor device of claim 8, wherein the plurality of semiconductor layers extend between and electrically couple the source/drain structures along a first direction, regions of the lower portion of the gate structure are disposed between the plurality of semiconductor layers and the source/drain structures, and the regions of the lower portion of the gate structure have cross-sectional shapes along the first direction having inner corner angles of about 90 to 105 degrees.

14. The semiconductor device of claim 8, wherein first surfaces of the lower portion of the gate structure and first surfaces of the inner spacers define an angle therebetween of about 165 to 180 degrees, wherein the first surfaces of the lower portion of the gate structure and the first surfaces of the inner spacers are both in contact with the plurality of intermediate layers.

15. A method, comprising:
forming a fin structure on a substrate that extends along a first lateral direction of the substrate, wherein the fin structure includes a plurality of alternating first semiconductor layers, second semiconductor layers, and diffusion cap layers between the first semiconductor layers and the second semiconductor layers, wherein the diffusion cap layers function as diffusion barriers between the first semiconductor layers and the second semiconductor layers;
forming an etch stop layer on the fin structure;
forming a dummy gate structure over a portion of the fin structure, wherein the dummy gate structure extends along the substrate in a second direction perpendicular to the first lateral direction, wherein portions of the etch stop layer are between the fin structure and the dummy gate structure;
lining sidewalls of the dummy gate structure with gate spacers, wherein the gate spacers and the fin structure are separated by the etch stop layer;
removing portions of the fin structure not underlying the dummy gate structure;
forming source/drain structures that are respectively coupled to ends of the fin structure, wherein the source/drain structures are formed in locations previously occupied by the portions of the fin structure;
removing the dummy gate structure to form a gate trench;
removing the first semiconductor layers such that the second semiconductor layers are vertically separated by one another by spaces; and
forming an active gate structure in the gate trench that wraps around each of the second semiconductor layers of the fin structure by filling the spaces therebetween wherein the diffusion cap layers are disposed between and separate the active gate structure and the second semiconductor layers.

16. The method of claim 15, wherein the diffusion cap layers each have a thickness of about 1 to 2 nanometers such that diffusion between the plurality of semiconductor layers is sufficiently impeded to prevent distortion of the plurality of semiconductor layers.

17. The method of claim 15, wherein the first semiconductor layers include silicon germanium, the second semiconductor layers include silicon, and the diffusion cap layers reduce diffusion of germanium from the first semiconductor layers to the second semiconductor layers.

18. The method of claim 15, wherein the diffusion cap layers include silicon nitride.

19. The method of claim 15, wherein the second semiconductor layers extend between and electrically couple source/drain structures along a first direction, regions of the active gate structure are disposed between the second semiconductor layers and the source/drain structures, wherein the second semiconductor layers each have heights normal to the first direction of about 8 to 9 nanometers, and the regions of the active gate structure each have heights normal to the first direction of about 6 to 7 nanometers.

20. The method of claim 15, further comprising inner spacers vertically disposed between the second semiconductor layers and separating the active gate structure from source/drain structures, wherein first surfaces of the active gate structure and first surfaces of the inner spacers define an angle therebetween of about 165 to 180 degrees, wherein the first surfaces of the active gate structure and the first surfaces of the inner spacers are both in contact with the diffusion cap layers.
